(19) United States
(12) Patent Application Publication
(10) Pub. No.: US 2011/0112780 A1
(43) Pub. Date: May 12, 2011

(54) Electrical power consumption measuring system

(76) Inventor: David Moss, Tucson, AZ (US)

(21) Appl. No.: 12/590,340

(22) Filed: Nov. 6, 2009

(51) Int. Cl. G01R 21/133

(52) U.S. Cl. 702/62

(57) ABSTRACT

An electrical power consumption measuring system that is capable of determining and presenting the power consumed by individual appliances at a home or premises. The system collects operational state information about a plurality of appliances, each connected to a power line to which is also attached a power meter, and it can determine which applies are on or off, and how much power each of the appliances consume.

### CROSS REFERENCES TO RELATED APPLICATIONS

The present patent application is related to, claims priority to, and makes reference to a co-pending application, entitled “A MONITORING SYSTEM FOR COLLECTION AND DISTRIBUTION OF A POWER CONSUMPTION INFORMATION”, filed on Mar. 31, 2009, docket number GWPP2009U1.

The present patent application is also related to and makes reference to a co-pending application, entitled “WEB BASED MONITORING, MANAGEMENT AND CONTEST BASED ON COLLECTED POWER CONSUMPTION DATA”, filed on Mar. 31, 2009, docket number GWPP2009U2.

The complete subject matter of the two above-referenced United States patent applications is hereby incorporated herein by reference, in their entirety. The present patent application and the above-referenced United States patent applications share the same inventors and have the same filing date.

### BACKGROUND

1. Technical Field

The present invention relates generally to energy saving and power consumption monitoring and particularly to a wireless sensing device that can be located adjacent to or in proximity to an appliance, such as a HVAC system; that monitors usage patterns and correlates that to power consumption.

2. Related Art

Power consuming appliances are becoming ubiquitous. People use electrical tools and appliances all over their residences. Some electrical appliances are turned on and seldom turned off, even when the user does not need the appliance or make use of it. Most people living in a modern house have a TV, a refrigerator, a washing machine, a washer, a dryer, a heating system, an air conditioner, etc. Most of these devices consume a lot of power when they are plugged into power outlets, some even when they are not being used.

Every day people use a lot of electricity for running appliances such as a refrigerator, but they don't know how much power these appliances consume. The doors of refrigerators are opened several times a day, and often for extended durations, thereby causing the refrigerator to use more power to keep things cool. Quite often the temperature settings on the refrigerator are inappropriate—set too high or set too low.

There are several types of appliances that consume a lot of energy. Most power meters show the amount of power/energy that is being consumed at a house. They are incapable of showing how much energy each appliance in the house/premises consumes, and how much it costs to operate each appliance. Even new smart meters are incapable of specifying how much energy each appliance in a house consumes, and how much it costs to operate them. At best, they can only estimate the total power consumption of a house.

Unfortunately, despite widespread acceptance of green house effects and despite rise in the price of crude oil, people have not been provided with effective power saving technologies. People are being encouraged to turn off light bulbs when they are not in a room. Some appliance can be turned off if they are not being used. However, turning off a refrigerator when a user is travelling it is not an option as food stored in the refrigerator is likely to get spoiled when it is turned off. Thus, effective power saving mechanisms are lacking for appliances such as refrigerators.

Often people do not know how much power they can save by following all the typical power saving recommendations. Well meaning individuals have no idea how effective all their power saving efforts has been. Even if one were to use green electrical appliances, one does not know if one can be more effective in saving power by adopting better usage patterns.

There is a problem educating users on effective power management techniques that saves them money by reducing power consumption of their refrigerators and other appliances. Quite often, these individuals who have lowered their electric bills do not know how much individual appliances have contributed towards the savings in energy bills.

One of the big energy intensive appliances at home are the HVAC systems that are used to heat houses in winter and cool them in summer. It is important to be able to monitor the energy consumption of HVAC systems, especially the legacy HVAC systems that are difficult to monitor or relocate, and sometimes even expensive to replace. If the heater or air conditioning is plugged in, the plug is usually difficult to get to and may not be a standard type of connection. Sometimes the HVAC system may be hard wired and their plugs cannot be replaced or modified. This makes it difficult to explicitly measure how much energy the heater or air units of the HVAC system consume.

Another important high energy consumption item on a monthly energy bill is the various lamps and lights that are left on, sometimes throughout the day. The use of various lamp systems need to be properly managed and they must be turned off when not needed, but there are no easy ways in which people can be coaxed into turning them off when not needed. Most people forget to turn the lights off, and they do not know when these lamps have been left on inadvertently. Often, people forget that they had left their lights on when they go on a vacation and come back to realize that the lights were on for the entire duration of their vacation.

In view of the foregoing considerations, it is clear that there is a need for an improved system and method for measuring power consumption and monitoring power usage.

### BRIEF SUMMARY OF THE INVENTION

The present invention is directed to apparatus and methods of operation that are further described in the following Brief Description of the Drawings, the Detailed Description of the Invention, and the claims. Other features and advantages of the present invention will become apparent from the following detailed description of the invention made with reference to the accompanying drawings.

### BRIEF DESCRIPTION OF THE DRAWINGS

FIG. 1 is a perspective block diagram of an electrical power consumption measuring system that is capable of determining and presenting the power consumed by individual appliances at a home or premises.

FIG. 2 is a perspective block diagram of a power consumption measuring system for a premises with a plurality of appliances, that shows the components of a wireless fingerprint device and a power meter that interact with each other to form part of a system to monitor energy consumption and operational state of appliances.

FIG. 3 is a flowchart of an exemplary operation of the electrical power consumption measuring system as it determines the power consumption of individual appliances in a house, wherein the house comprises a plurality of appliances connected to a power line, and a power meter monitors the total power consumption.

FIG. 4 is a perspective block diagram of a power monitoring system that works with legacy power meters.

FIG. 5 is a flow chart of an exemplary operation of the electrical power consumption measuring system as it identifies appliances that have changes their operational state based on appliance fingerprints.

### DETAILED DESCRIPTION OF THE DRAWINGS

The present invention provides an elegant means of monitoring energy consumption by individual appliances at a home or premises, such as a HVAC system or a refrigerator. The changes to total energy consumption at the house or premises is monitored and the identity of the actual appliance is determined based on pre-determined appliance power usage signatures, or alternatively by the use of pre-determined appliance fingerprints. User behavior is modified by recommending approaches to cut energy consumption by the appliances thereby providing savings and reducing the cost of operation.

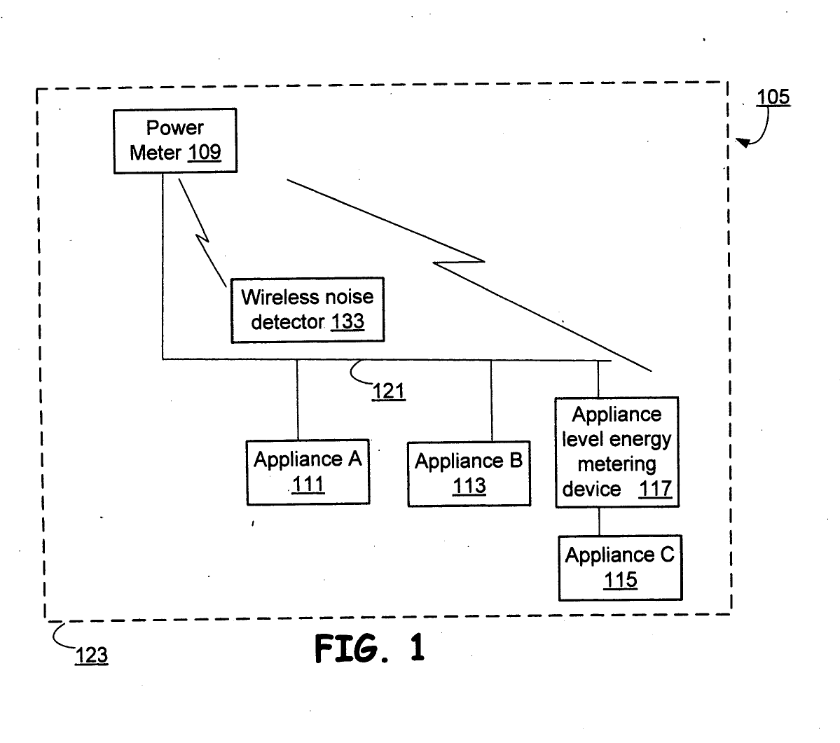

FIG. 1 is a perspective block diagram of an electrical power consumption measuring system 105 that is capable of determining and presenting the power consumed by individual appliances at a home or premises 123. The system 105 monitors power consumption by individual appliances in a premises (such as a house or building), wherein the premises comprises a plurality of appliances 111, 113, 115, each connected to a power line 121 to which is also attached a power meter 109. To train the system 105 initially and to collect appliance signatures from the appliances 111, 113, 115, an appliance level energy metering device 117 is employed that gathers power consumption data for the appliance and reports it to the power meter 109. It can report the power consumption data for an appliance connected to it, such as the appliance C 115, using wireless means (802.11a/b/g/n or Bluetooth, etc.) or over the power line 121.

The electrical power consumption measuring system 105 also comprises a wireless noise detector 133 that collects and communicates an appliance fingerprint for each appliance in the premises 123, as they are turned on, made operational (being used) or turned off. For example, it collects noise of different kinds when an appliance such as the appliance A 111 is started or turned off. Such noise can be electrical noise, mechanical noise (such as sounds) or vibrational noise, or a combination of all three types of noise.

The wireless noise detector 133 detects when the appliances 111, 113, 115 come on and when they are turned off and are capable of assembling an appliance usage data. It reports the start/stop and other events that it detects to the power meter 109. It also reports appliance usage data if necessary (duration of usage, frequency of usage, etc.). In one embodiment, the wireless communication means employed by the wireless noise detector 133 is a WiFi based communication link. Other alternate communications means are also contemplated, such as BlueTooth, IRDA, etc. To detect vibrations from appliances, wherein such vibrations indicate the operational state of an appliance, the wireless noise detector 133 employs appropriate vibration sensors. For example, the wireless sensing device, in one embodiment, employs a tilt sensor that can detect movements in one or 2 axis, that provide a binary output. Thus, for some embodiments, a simple 1- or 2-axis sensor with a binary output would suffice to detect vibrations. Specifically, in a 1-axis version, a metal ball rolls up and down inside a small ‘pipe’ and makes or breaks electrical contact. It can measure a change if the angle of the tilt is along the axis of the pipe, so the ball inside can roll from one side to the other.

In one embodiment, the wireless noise detector 133 employs a 2-axis tilt sensor. For example, it employs one where a metal ball moves in 2-dimensions in an enclosed circular arena. The metal ball in the sensor moves inside its enclosure whenever the wireless sensing device tilts along the X- or Y-axis and makes or breaks contact with electrical pads, which is detected and tracked.

The electrical power consumption measuring system 105 monitors power consumption in the premises 123, wherein the premises comprises appliances 111, 113, 115 that consume electrical power. The electrical power consumption measuring system measures an amount of energy consumed by each of the appliances 111, 113, 115 and stores it as an appliance signature. The electrical power consumption measuring system 105 computes an usage cost for each appliances 111, 113, 115 and presents the usage cost to a user, based on the amount of energy consumed by each of the appliances. It also monitors usage of the appliances over a period of time and computes a cost of operating for them.

In general, the electrical power consumption measuring system 105 determines and registers an appliance signature comprising an energy consumption data and an appliance fingerprint comprising at least an electrical noise for each of the appliances in the premises, as they are turned on or off. It also monitors a change in total energy consumption for the premises 123 and identifies a change in operational state of one of the appliances 111, 113, 115 as the potential reason for such a change. It also detects an observed appliance fingerprint to confirm the appropriate one of appliances 111, 113, 115 as the reason for the change in total energy consumption for the premises 123. It records a change in operational state of the appropriate one of the appliances 111, 113, 115 in the premises.

The electrical power consumption measuring system 105 monitors changes in total energy consumption when any of the appliances 111, 113, 115 is turned on or off, and it also identifies the appropriate one of the appliances as the actual appliance that was turned on or off. It also deduces the amount of energy that an individual one of the appliances 111, 113, 115 consumes when it is turned on, without having to actively and continuously monitor the energy consumption of the at least one appliance.

During an initial training mode, the electrical power consumption measuring system 105 prompts the user to notify when each of the appliances 111, 113, 115 is turned on or off and it registers a change in power consumption noticed by the power meter 109 as an appliance electrical signature for that associated appliance. Subsequently, the electrical power consumption measuring system 105 determines a change in total home energy consumption in real-time (when the system in out of training mode to operational mode) when each of the at least one appliance is turned on or off and identifies the actual appliance that is the cause for such a change, i.e. it determines which of the appliances 111, 113, 115 was turned on or off, causing the change. Thus, based on the known (or pre-determined) appliance electrical signature of the appliances 111, 113, 115, the electrical power consumption measuring system 105 identifies one of them as being turned on or off, or having changed its state.

In one embodiment, the electrical power consumption measuring system 105 employs the appliance level energy metering device 117 to determine appliance signatures of the appliances (one at a time). The appliance level energy metering device 117 is used with any of the appliances 111, 113, 115 to determine a corresponding energy consumption profile data and an appliance electrical signature. It reports them to the power meter 109 where it is stored. Thus, the electrical power consumption measuring system 105 acquires and stores the energy consumption profile data and the appliance electrical signature from the appliance level energy metering device 117 when the appliance level energy metering device 117 is used with any appliances 111, 113, 115. The electrical power consumption measuring system 105 subsequently detects the identity of the appliances 111, 113, 115 as they are turned off or turned on based on comparison of changes in a total energy consumption data for the premises 123 (detected by the power meter 109) with the appliance electrical signatures for the appliances 111, 113, 115 stored at the power meter 109.

In one embodiment, the electrical power consumption measuring system 105 comprises an electrical monitor that monitors the power line 121 in the premises that monitors transient and continuous noise on the power line 121. It then determines an electrical fingerprint for each of the appliances 111, 113, 115 as they are turned on, made operational, and turned off. The electrical monitor reports the electrical fingerprint to the power meter 109 for storage. The electrical power consumption measuring system 105 uses the electrical fingerprint for each of the appliances 111, 113, 115 to determine an operational state for each of the appliances 111, 113, 115. The electrical power consumption measuring system 105 also computes a total home energy consumption information for the premises 123 based on the known current operational states of the appliances 111, 113, 115.

In one embodiment, the electrical power consumption measuring system 105 determines when each of the plurality of appliances 111, 113, 115 is turned on or off based on monitoring and detecting a transient and continuous noise from specific locations in the premises (employing the wireless noise detector 133), and also determines corresponding changes to the total energy consumption data for the premises 123 due to such changes in operational states of the appliances 111, 113, 115.

In a related embodiment, the electrical power consumption measuring system 105 determines an appliance energy signature for each of the plurality of appliances 111, 113, 115. It also determines or computes a cyclic usage trend for each of the plurality of appliances 111, 113, 115, and a lifestyle profile for the users of the premises 123.

The electrical power consumption measuring system 105 recognizes automatically when an appliance turns on or off, and then maps its power consumption contribution to the total home energy consumption. Thus, appliances 111, 113, 115 can be recognized to be on or off in at least four related ways:

A) By recognize the change in total home energy consumption in real-time at the power meter 109. This can be combined with user interaction where the user explicitly tells the system when an appliances 111, 113, 115 is turned on or off.

B) Plugging the appliances 111, 113, 115 into an appliance level energy metering device 117 for a period of time that allows the individual appliance's electrical consumption signature to be acquired and mapped to the total home energy consumption.

C) Attaching the wireless noise detector 133 (or similar device) to the appliances 111, 113, 115 to know when it is active or not (i.e. a wireless device that connects to the washer or dryer that detects movement, or a wireless device that listens to the compressor on the refrigerator). A version of the wireless noise detector 133 is employed for such detection of appliance state.

D) Monitoring the transient and continuous noise on the power line 121 from any point in the house to identify noise generated by appliances 111, 113, 115 when they turn on or off. Each appliance 111, 113, 115 produces a slightly different noise spectrum ‘fingerprint’ that can be used to uniquely identify the appliance turning on, staying active, or turning off, which is mapped to the total home energy consumption.

In all cases, the change in on/off state of an appliance (or change in operational state, in general) is mapped to the change in total building electrical consumption at the power meter 109.

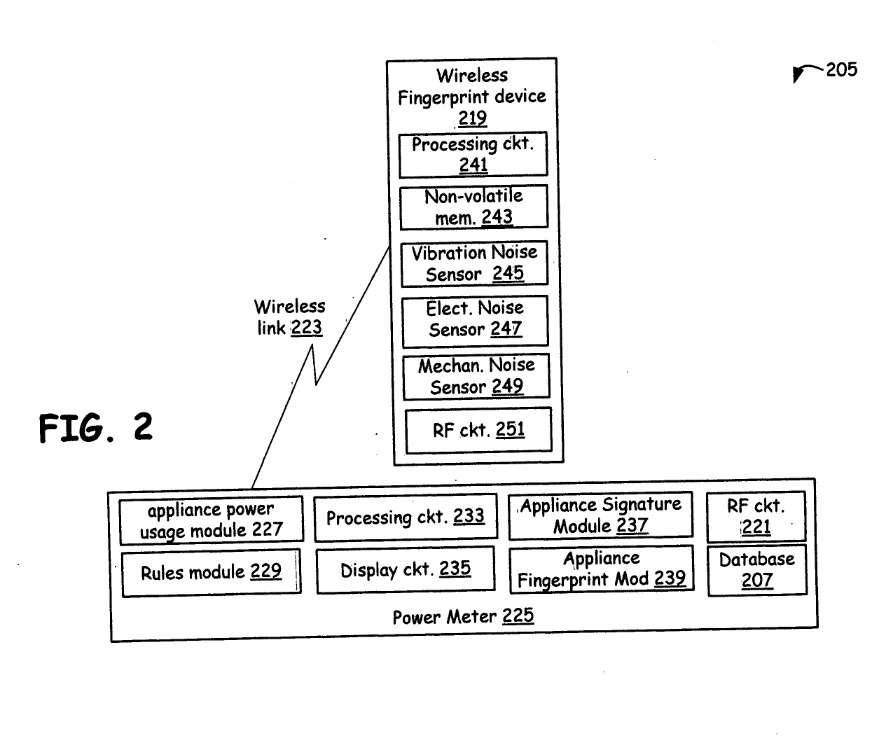

FIG. 2 is a perspective block diagram of a power consumption measuring system 205 for a premises with a plurality of appliances, that shows the components of a wireless fingerprint device 219 and a power meter 225 that interact with each other to form part of a system to monitor energy consumption and operational state of appliances. The wireless fingerprint device 219 and the power meter 225 employ a wireless link 223 to communicate, such as wireless links that employ an 802.11 based protocol or a similar protocol.

The wireless fingerprint device 219 comprises a processing circuitry 241 and a non-volatile memory 243 that is used to store rules, configurations, collected data, measurements, etc. It also comprises a vibration noise sensor 245 to detect vibrations (caused by appliances turning on, off, etc.), an electrical noise sensor 247 to detect electrical noise generated as appliances change their operational state, and a mechanical nose sensor 249 to detect audible mechanical noises due to movement of parts in an appliance. It also comprises a radio frequency (RF) circuitry 251 to communicate employing wireless communication protocols.

The power meter 225 comprises a processing circuitry 233, a display circuitry 235, an appliance power usage module 227 that is used to process store collected data, and a rules module 229 that is used to manage the wireless fingerprint device 219, that also manages rules to be transferred to the wireless fingerprint device 219. It also comprises a an RF circuitry 221 that supports communication with the wireless fingerprint device 219, an appliance signature module 237 that determines appliance signatures, and an appliance fingerprint module 239 that keeps track of fingerprints associated with appliance startup, change in various operational states and appliance shutdown. It also comprises a database 207 that stores appliances fingerprints, appliance signatures, etc. The power meter 225 communicates user generated rules or default rules to the wireless fingerprint device 219. The wireless fingerprint device 219 operates its fingerprint data collection and measurement operations based on these rules.

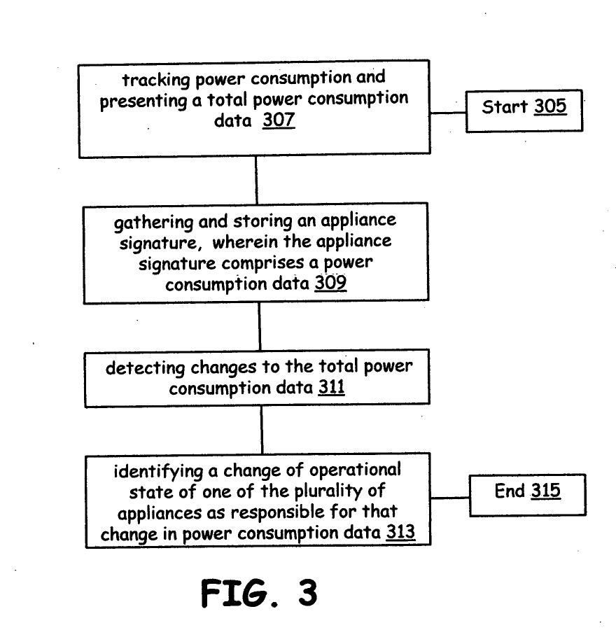

FIG. 3 is a flowchart of an exemplary operation of the electrical power consumption measuring system 105 as it determines the power consumption of individual appliances in a house, wherein the house comprises a plurality of appliances connected to a power line, and a power meter monitors the total power consumption. At a start block 305, the operation starts. Then at a next block 307, the electrical power consumption measuring system 105 instructs the power meter 109 to track power consumption and presents a total power consumption data collected/computed by the power meter 109.

Then at a next block 309, gathering and storing appliance signatures for each of the plurality of appliances 111, 113, 115 begins, wherein the appliance signature comprises a power consumption data for that appliance. Such gathering of appliance signatures is conducted in a “training mode” or “setup mode” with the use of the appliance level energy metering device 117 is some embodiments.

Then, at a next block 311, the power meter 109 detects changes to the total power consumption data that it monitors/computes. Changes to the total power consumption data typically indicate that an operational state change has occurred in one or more appliances 111, 113, 115. For example, appliance A 111 may have been turned on, causing total power consumption to go up.

Then, at a next block 313, the electrical power consumption measuring system 105 identifies a change of operational state of one of the plurality of appliances as responsible for that change in total power consumption data. Identification of the actual appliance that caused the change in total power consumption is done based on known/pre-determined appliance signatures.

The operation then terminates at a next end block 315.

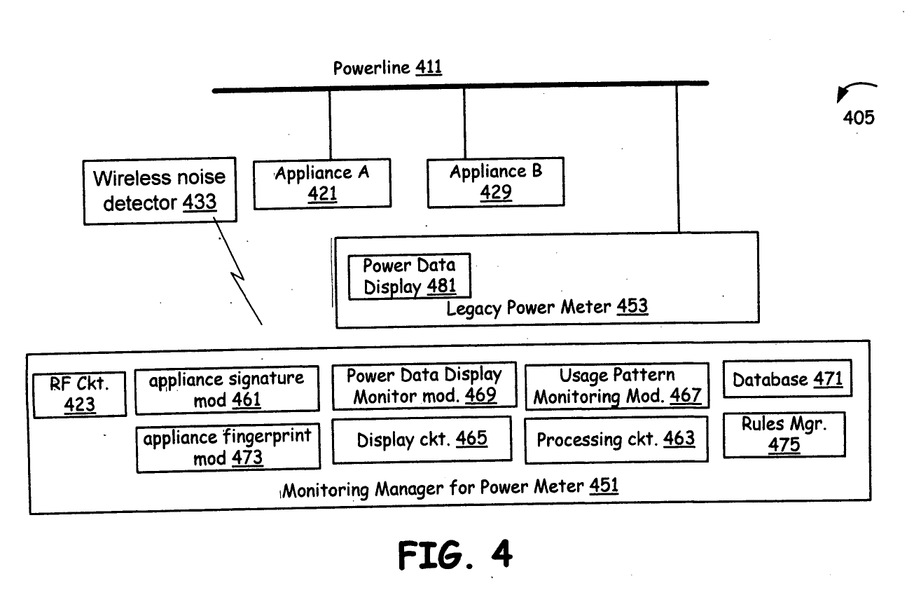

FIG. 4 is a perspective block diagram of a power monitoring system 405 that works with legacy power meters 453. The power monitoring system 405 comprises a monitoring manager for power meter 451 that is capable of monitoring power consumption data collected and displayed, in analog fashion or in digital mode, by a legacy power meter 453. The monitoring manager for power meter 451 collects appliance fingerprints wirelessly from a wireless noise detector 433, that operates similarly to the wireless noise detector 133 of FIG. 1.

The monitoring manager for power meter 451 comprises a processing circuitry 463, an RF radio communication circuitry 423, an appliance signature module 461, an appliance fingerprint module 473, a display circuitry 465, a rules manager 475, a database 471, an usage pattern monitoring module 467, and the power data display monitoring module 469. The monitoring manager for power meter 451 makes it possible to collect appliance fingerprints of the appliances 421, 429. These are stored in the database 471. When an appliance such as appliance A 421 is turned off, the monitoring manager for power meter 451 notices a change in total power consumption data that is read from the power data display 481 by the power data display monitoring module 469. It also receives a notification from the wireless nose detector 433 along with noise data. Using its known fingerprint data stored in the database 471, it identifies the actual appliance that was turn off (in this case appliance A 421).

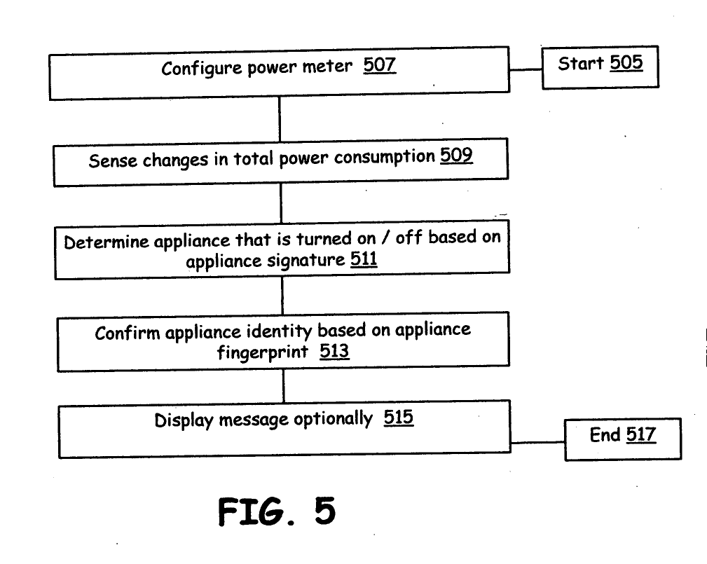

FIG. 5 is a flow chart of an exemplary operation of the electrical power consumption measuring system 105 as it identifies appliances that have changes their operational state based on appliance fingerprints. The operation starts at a start block 505 when the power meter 109 is set into operational mode after collecting appliance signatures (and perhaps even appliance fingerprints) in a setup mode or initialization mode. At a next block 507, the power meter 109 is configured with appliance signatures and known appliance fingerprints. Then, at a next block 509, the power meter 109 senses changes in total power consumption data. Then, at a next block 511, it determines if any of the appliances are turned on/turned off (or change their operational state), such determination is based on observed change in total power consumption and known appliance signatures 511.

At a next lock 513, the power meter confirms the appliance identity based on appliance fingerprint. Such appliance fingerprints are stored in the database, and are retrieved to compare reference fingerprints (from the database) with fingerprints reported by the wireless noise detector 133 (or by other monitors or sensors, if present). At a next block 515, the power meter displays a message optionally, to inform a user that a particular appliance has changed its state, or that cost of using the appliance has been computed and is displayed, etc.

Finally, the operation terminates at an end block 517.

As one of ordinary skill in the art will appreciate, the terms “operably coupled” and “communicatively coupled,” as may be used herein, include direct coupling and indirect coupling via another component, element, circuit, or module where, for indirect coupling, the intervening component, element, circuit, or module does not modify the information of a signal but may adjust its current level, voltage level, and/or power level. As one of ordinary skill in the art will also appreciate, inferred coupling (i.e., where one element is coupled to another element by inference) includes direct and indirect coupling between two elements in the same manner as “operably coupled” and “communicatively coupled.”

The present invention has also been described above with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claimed invention.

The present invention has been described above with the aid of functional building blocks illustrating the performance of certain significant functions. The boundaries of these functional building blocks have been arbitrarily defined for convenience of description. Alternate boundaries could be defined as long as the certain significant functions are appropriately performed. Similarly, flow diagram blocks may also have been arbitrarily defined herein to illustrate certain significant functionality. To the extent used, the flow diagram block boundaries and sequence could have been defined otherwise and still perform the certain significant functionality. Such alternate definitions of both functional building blocks and flow diagram blocks and sequences are thus within the scope and spirit of the claimed invention.

One of average skill in the art will also recognize that the functional building blocks, and other illustrative blocks, modules and components herein, can be implemented as illustrated or by discrete components, application specific integrated circuits, processors executing appropriate software and the like or any combination thereof.

Moreover, although described in detail for purposes of clarity and understanding by way of the aforementioned embodiments, the present invention is not limited to such embodiments. It will be obvious to one of average skill in the art that various changes and modifications may be practiced within the spirit and scope of the invention, as limited only by the scope of the appended claims.

What is claimed is:

1. An electrical power consumption measuring system that monitors power consumption in a premises, wherein the premises comprises at least one appliance that consumes electrical power, the electrical power consumption measuring system comprising:
the electrical power consumption measuring system measuring an amount of energy consumed by each of the at least one appliance and storing it as an appliance signature;
the electrical power consumption measuring system computing an usage cost for each of the at least one appliance and presenting the usage cost to a user, based on the amount of energy consumed by each of the at least one appliance; and
the electrical power consumption measuring system monitoring usage of the at least one appliance over a period of time and computing a cost of operating for each of the at least one appliance.

2. The electrical power consumption measuring system of claim 1 wherein the electrical power consumption measuring system determines and registers an appliance signature comprising an energy consumption data and an appliance fingerprint comprising electrical noise for each of the at least one appliance in the premises as they are turned on or off.

3. The electrical power consumption measuring system of claim 2 further comprising:
the electrical power consumption measuring system monitoring a change in total energy consumption for the premises and identifying a change in operational state of one of the at least one appliance as the potential reason for the change,
the electrical power consumption measuring system detecting an observed appliance fingerprint to confirm the one of the at least one appliance as the reason for the change; and
the electrical power consumption measuring system recording a change in operational state of the associated one of the at least one appliance in the premises.

4. The electrical power consumption measuring system of claim 1 wherein the electrical power consumption measuring system monitors changes in total energy consumption when any of the at least one appliance is turned on or off, and also identifies one Of the at least one appliance as the actual appliance that was turned on or off.

5. The electrical power consumption measuring system of claim 4 wherein the electrical power consumption measuring system deduces the amount of energy that an individual one of the at least one appliance consumes when it is turned on, without having to actively and continuously monitor the energy consumption of the at least one appliance.

6. The electrical power consumption measuring system of claim 4 further comprising:
the electrical power consumption measuring system prompting the user to notify when each of the at least one appliance is turned on or off during an initial training mode and registering a change in power consumption as an appliance electrical signature for that associated one of the at least one appliance;
the electrical power consumption measuring system determining a change in total home energy consumption in real-time during a subsequent operational mode when each of the at least one appliance is turned on or off; and
the power consumption measuring system determining which of the at least one appliance is turned on or off, based on the appliance electrical signature of that one of the at least one appliance.

7. The electrical power consumption measuring system of claim 4 further comprising:
an appliance level energy metering device that can be used with any of the at least one appliance to determine a corresponding energy consumption profile data and an appliance electrical signature;
the electrical power consumption measuring system acquiring and storing the energy consumption profile data and the appliance electrical signature from the appliance level energy metering device when the appliance level energy metering device is used with any of the at least one appliance; and
the electrical power consumption measuring system subsequently detecting the identity of those of the at least one appliance as they are turned off or turned on based on comparison of changes in a total energy consumption data for the premises with the appliance electrical signatures for the at least one appliance.

8. The electrical power consumption measuring system of claim 1 further comprising:
an electrical monitor that monitors a power line in the premises;
the electrical monitor monitoring transient and continuous noise on the power line and determining an electrical fingerprint for each of the at least one appliance as they are turned on, made operational, and turned off; and
the electrical power consumption measuring system using the electrical fingerprint for each of the at least one appliance to determine an operational state for each of the at least one appliance and also computing a total home energy consumption information for the premises.

9. A power consumption measuring system for a premises with a plurality of appliances, the power consumption measuring system comprising:
the power consumption measuring system determining in real-time a total energy consumption data for the premises;
the power consumption measuring system identifying incremental changes to the total energy consumption data as each of the plurality of appliances is turned on or off, thereby determining power consumption due to each of the plurality of appliances; and
the power consumption measuring system determining the cost of operating each of the plurality of appliances at specific periods during a day and reporting it to the user.

9. The power consumption measuring system of claim 9 wherein, in real time, the power consumption measuring system determines the cost of operating each of the plurality of appliances and reports it to the user along with suggestions for operating each of the plurality of appliances during an alternative period in order to reduce the cost of operating them.

10. The power consumption measuring system of claim 9 wherein the power consumption measuring system determines those of the plurality of appliances that are currently operating, based on total energy consumption data for the premises determined in real-time.

11. The power consumption measuring system of claim 9 wherein the power consumption measuring system determines when each of the plurality of appliances is turned on or off based on monitoring and detecting a transient and continuous electrical noise on a power line in the premises, and also determines corresponding changes to the total energy consumption data for the premises.

12. The power consumption measuring system of claim 9 wherein the power consumption measuring system determines when each of the plurality of appliances is turned on or off based on monitoring and detecting a transient and continuous noise from specific locations in the premises, and also determines corresponding changes to the total energy consumption data for the premises.

13. The power consumption measuring system of claim 9 wherein the power consumption measuring system determines an appliance energy signature for each of the plurality of appliances, a cyclic usage trend for each of the plurality of appliances, and a lifestyle profile for the users of the premises.

14. A method of determining the power consumption of individual appliances in a house by a power meter system, the house comprising a plurality of appliances connected to a power line monitored by a power meter, the method comprising:
tracking power consumption and presenting a total power consumption data by the power meter;
gathering and storing an appliance signature for each of the plurality of appliances, wherein the appliance signature comprises a power consumption data for that appliance;
detecting changes to the total power consumption data; and
identifying a change of operational state of one of the plurality of appliances as responsible for that change.

15. The method of determining the power consumption of claim 14 further comprising:
collecting and storing an appliance fingerprint for each of the plurality of appliances, wherein the appliance fingerprint comprises a noise data for that appliance.

16. The method of determining the power consumption of claim 15 wherein the noise data is at least one of an electrical noise data, a mechanical noise data and a vibrational noise data.

17. The method of determining the power consumption of claim 15 wherein collecting comprises:
recording noise generated by each of the plurality of appliances when they turned on, when they are operational and when they or turned off; and
associating the noise recorded with the appropriate ones of the plurality of appliances.

18. The method of determining the power consumption of claim 15 wherein each of the plurality of appliances produces a slightly different appliance fingerprint that can be used to uniquely identify an event wherein that appliance turned on, is kept active, or is turned off, wherein the event is factored in the determination of a current value for the total power consumption data.

19. The method of determining the power consumption of claim 15 further comprising:
recognizing when one of the plurality of appliances is turned on or turned off without explicit user interaction, based on comparing the appliance electrical signature for each of the plurality of appliances to changes to the total power consumption data monitored by the power meter, or based on appliance fingerprint collected.

20. The method of determining the power consumption of claim 15 wherein identifying a change of operational state of one of the plurality of appliances is conducted based on an appliance fingerprint collected by the power meter.
